(19) United States
(12) Patent Application Publication
(10) Pub. No.: US 2025/0359435 A1
(43) Pub. Date: Nov. 20, 2025

(54) DISPLAY APPARATUS AND METHOD OF MANUFACTURING THE SAME

(71) Applicant: Samsung Display Co., Ltd., Yongin-si (KR)

(72) Inventors: Kicheol SONG, Yongin-si (KR); Youngwoo CHOI, Yongin-si (KR); Jongho SHIN, Yongin-si (KR); Changwoo LEE, Yongin-si (KR)

(21) Appl. No.: 19/015,436

(22) Filed: Jan. 9, 2025

(30) Foreign Application Priority Data
May 16, 2024 (KR) 10-2024-0064134

(51) Int. Cl. H10K 59/122; H10K 59/12

(52) U.S. Cl. CPC H10K 59/122; H10K 59/1201

(57) ABSTRACT

A display apparatus includes a substrate having relatively high transparency and display elements, the substrate including a component area and a main display area at least partially surrounding the component area, the component area including sub-display areas and transmission areas and the display elements disposed on the main display area and the sub-display areas. The substrate includes a first organic layer, a first barrier layer on the first organic layer, a second organic layer on the first barrier layer, and a second barrier layer on the second organic layer. Each of the first organic layer and the second organic layer includes a cured product of polyamic acid prepared by polymerizing an oxydiphthalic anhydride, a biphenyl-tetracarboxylic dianhydride, a 4-aminophenyl-4-aminobenzoate, a 4,4′-oxydianiline, and a p-phenylenediamine.

This application claims priority to Korean Patent Application No. 10-2024-0064134, filed on May 16, 2024, and all the benefits accruing therefrom under 35 U.S.C. § 119, the content of which in its entirety is herein incorporated by reference.

### BACKGROUND

### 1. Field

Embodiments relate to a display apparatus and a method of manufacturing the same, and more particularly, to a display apparatus including a substrate having relatively high transparency and a method of manufacturing the same.

### 2. Description of the Related Art

Recently, display apparatuses have been used for various applications. For various purposes, the display apparatus may include a display panel and components, and the components may be electronic elements using light or sound.

Research on display apparatuses to add functions other than image display to the inside of a display area is continuing as a way to expand the area occupied by the display area and simultaneously add various functions. To this end, the display area of the display apparatus may include a transmission area, which is an area through which light emitted from or incident on the components is transmitted. Using light incident through the transmission area, the components may detect or recognize an object or a user.

### SUMMARY

However, such conventional display apparatuses have a problem in that the transparency of the substrate included in the display apparatus is low.

Embodiments include a display apparatus including a substrate having relatively high transparency and a method of manufacturing the same to solve various problems including the problems described above. However, these features are exemplary and do not limit the scope of the disclosure.

Additional features will be set forth in part in the description which follows and, in part, will be apparent from the description, or may be learned by practice of the presented embodiments of the disclosure.

In an embodiment of the disclosure, a display apparatus includes a substrate and display elements, the substrate includes a component area and a main display area at least partially surrounding the component area, the component area including sub-display areas and transmission areas, and the display elements disposed on the main display area and the sub-display areas, and the substrate includes a first organic layer, a first barrier layer on the first organic layer, a second organic layer on the first barrier layer, and a second barrier layer on the second organic layer, each of the first organic layer and the second organic layer including a cured product of polyamic acid prepared by polymerizing an oxydiphthalic anhydride, a biphenyl-tetracarboxylic dianhydride, a 4-aminophenyl-4-aminobenzoate, a 4,4′-oxydianiline, and a p-phenylenediamine.

In an embodiment, a ratio of a sum of a mole number of the oxydiphthalic anhydride and a mole number of the biphenyl-tetracarboxylic dianhydride to a sum of a mole number of the 4-aminophenyl-4-aminobenzoate, a mole number of the 4,4′-oxydianiline, and a mole number of p-phenylenediamine may be 1:1.

In an embodiment, when the mole number of the oxydiphthalic anhydride is expressed as “a” and the mole number of the biphenyl-tetracarboxylic dianhydride is expressed as “b,” the mole number of the oxydiphthalic anhydride and the mole number of the biphenyl-tetracarboxylic dianhydride may satisfy Equation 1 and Equation 2:

$$0.1 \leq \frac{a}{a + b} \leq 0.5 \qquad Equation 1$$

$$0.5 \leq \frac{b}{a + b} \leq 0.9 . \qquad Equation 2$$

In an embodiment, when the mole number of the APAB is expressed as “c,” the mole number of the ODA is expressed as “d,” and the mole number of the PPD is expressed as “e,” the mole number of the APAB, the mole number of the ODA, and the mole number of the PPD may satisfy Equation 3, Equation 4, and Equation 5:

$$0.1 \leq \frac{c}{c + d + e} \leq 0.3 \qquad Equation 3$$

$$0.1 \leq \frac{d}{c + d + e} \leq 0.3 \qquad Equation 4$$

$$0.4 \leq \frac{e}{c + d + e} \leq 0.8 . \qquad Equation 5$$

In an embodiment, a transmittance of each of the first organic layer and the second organic layer at 450 nanometers (nm) may be 80% or more.

In an embodiment, a coefficient of thermal expansion (“CTE”) of each of the first organic layer and the second organic layer may be less than 12 parts-per-million per degree Celsius.

In an embodiment, a thermal decomposition temperature of each of the first organic layer and the second organic layer may be greater than 500 degrees Celsius (° C.).

In an embodiment, the first barrier layer may be in direct contact with the second organic layer.

In an embodiment of the disclosure, a method of manufacturing a display apparatus includes manufacturing a substrate including a component area and main display area at least partially surrounding the component area, the component area including sub-display areas and transmission areas, and forming a display element on the main display area and the sub-display areas, wherein the manufacturing the substrate includes preparing polyamic acid by polymerizing a dianhydride compound and a diamine compound, forming a preliminary organic layer by applying the polyamic acid along with an organic solvent onto a manufacturing substrate and removing at least a portion of the organic solvent, and forming an organic layer by curing the preliminary organic layer, wherein the dianhydride compound includes an oxydiphthalic anhydride and a biphenyl-tetracarboxylic dianhydride, and the diamine compound includes a 4-aminophenyl-4-aminobenzoate, a 4,4′-oxydianiline, and a p-phenylenediamine.

In an embodiment, a ratio of a sum of a mole number of the oxydiphthalic anhydride and a mole number of the biphenyl-tetracarboxylic dianhydride to a sum of a mole number of the APAB, a mole number of the ODA, and a mole number of PPD may be 1:1.

In an embodiment, when the mole number of the oxydiphthalic anhydride is expressed as “a” and the mole number of the biphenyl-tetracarboxylic dianhydride is expressed as “b,” the mole number of the oxydiphthalic anhydride and the mole number of the biphenyl-tetracarboxylic dianhydride may satisfy Equation 1 and Equation 2:

$$0.1 \leq \frac{a}{a + b} \leq 0.5 \qquad Equation 1$$

$$0.5 \leq \frac{b}{a + b} \leq 0.9 . \qquad Equation 2$$

In an embodiment, when the mole number of the APAB is expressed as “c,” the mole number of the ODA is expressed as “d,” and the mole number of the PPD is expressed as “e,” the mole number of the APAB, the mole number of the ODA, and the mole number of the PPD may satisfy Equation 3, Equation 4, and Equation 5:

$$0.1 \leq \frac{c}{c + d + e} \leq 0.3 \qquad Equation 3$$

$$0.1 \leq \frac{d}{c + d + e} \leq 0.3 \qquad Equation 4$$

$$0.4 \leq \frac{e}{c + d + e} \leq 0.8 . \qquad Equation 5$$

In an embodiment, a transmittance of the organic layer at 450 nm may be 80% or more.

In an embodiment, a CTE of the organic layer may be less than 12 parts-per-million per degree Celsius.

In an embodiment, a thermal decomposition temperature of the organic layer may be greater than 500° C.

In an embodiment, the forming the organic layer by curing the preliminary organic layer may include first heat treating the preliminary organic layer to increase the temperature of the preliminary organic layer from a first temperature to a second temperature higher than the first temperature, second heat treating the preliminary organic layer to increase the temperature of the preliminary organic layer from the second temperature to a third temperature higher than the second temperature, third heat treating the preliminary organic layer to increase the temperature of the preliminary organic layer from the third temperature to a fourth temperature higher than the third temperature, and cooling the preliminary organic layer to decrease the temperature of the preliminary organic layer from the fourth temperature to a fifth temperature lower than the fourth temperature, wherein in the first heat treating the preliminary organic layer, a heating rate of the preliminary organic layer may be in a range of about 2.50 degrees Celsius per minute (° C./min) to about 3.33° C./min.

In an embodiment, in the first heat treating the preliminary organic layer, the temperature of the preliminary organic layer may be increased from the first temperature to the second temperature and the temperature of the preliminary organic layer may be maintained at the second temperature.

In an embodiment, the first temperature may be 80° C., the second temperature may be 180° C., and in the first heat treating the preliminary organic layer, the time desired to increase the temperature of the preliminary organic layer from the first temperature to the second temperature may be about 30 minutes to about 40 minutes.

In an embodiment, in the second heat treating the preliminary organic layer, the temperature of the preliminary organic layer may be increased from the second temperature to the third temperature and the temperature of the preliminary organic layer may be maintained at the third temperature, wherein the second temperature may be 180° C. and the third temperature may be 250° C., and in the second heat treating the preliminary organic layer, a heating rate of the preliminary organic layer may be in a range of about 1.56° C./min to about 2.00° C./min.

In an embodiment, in the third heat treating the preliminary organic layer, the temperature of the preliminary organic layer may be increased from the third temperature to the fourth temperature and the temperature of the preliminary organic layer may be maintained at the fourth temperature, wherein the third temperature may be 250° C. and the fourth temperature may be 470° C., and in the third heat treating the preliminary organic layer, a heating rate of the preliminary organic layer may be in a range of about 5.95° C./min to about 8.15° C./min.

Other features, features and advantages other than those described above will become apparent from the detailed description, claims and drawings for implementing the disclosure.

### BRIEF DESCRIPTION OF THE DRAWINGS

The above and other features and advantages of illustrative embodiments of the disclosure will be more apparent from the following description taken in conjunction with the accompanying drawings, in which:

FIG. 1 is a plan view schematically showing an embodiment of a display apparatus;

FIG. 2 is a cross-sectional view schematically showing a part of the display apparatus of FIG. 1;

FIG. 3 is a plan view schematically showing an embodiment of a part of a component area of a display apparatus;

FIG. 4 is a cross-sectional view schematically showing a cross section taken along line I-I′ of the display apparatus of FIG. 1;

FIG. 5 is a cross-sectional view schematically showing a cross section taken along lines II-II′ and III-III′ of the display apparatus of FIG. 3;

FIG. 6 is a cross-sectional view schematically showing a substrate of FIGS. 4 and 5;

FIG. 7 is a flowchart illustrating an embodiment of a part of a method of manufacturing a display apparatus;

FIG. 8 is a flowchart illustrating an embodiment of a part of a method of manufacturing a display apparatus;

FIG. 9 is a flowchart illustrating an embodiment of a part of a method of manufacturing a display apparatus 1; and

FIG. 10 is a graph showing the temperature of a preliminary organic layer in forming an organic layer.

### DETAILED DESCRIPTION

Reference will now be made in detail to embodiments, embodiments of which are illustrated in the accompanying drawings, wherein like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Because the disclosure may have diverse modified embodiments, embodiments are illustrated in the drawings and are described in the detailed description. An effect and a characteristic of the disclosure, and a method of accomplishing these will be apparent when referring to embodiments described with reference to the drawings. The disclosure may, however, be embodied in many different forms and should not be construed as limited to the embodiments set forth herein.

It will be understood that although the terms “first,” “second,” etc. used herein may be used herein to describe various components, these components should not be limited by these terms. These terms are only used to distinguish one component from another.

An expression used in the singular encompasses the expression of the plural, unless it has a clearly different meaning in the context.

It will be further understood that the terms “comprises” and/or “comprising” used herein specify the presence of stated features or components, but do not preclude the presence or addition of one or more other features or components.

In the specification, “A and/or B” refers to A, B, or A and B. In addition, “at least one of A and B” refers to A, B, or A and B.

In the specification, when various components such as layers, films, regions, or plates are referred to as being “on” another component, this may include not only a case in which the layers, films, regions, or plates are “immediately on” the another component but also a case in which other components may be placed therebetween.

It will be understood that when a layer, region, or component is referred to as being “connected to” another layer, region, or component, the layer, region, or component may be directly connected to the another layer, region, or component, and/or indirectly connected to the another layer, region, or component as intervening layer, region, or component is present. For example, it will be understood that when a layer, region, or component is referred to as being “electrically connected to” another layer, region, or component, the layer, region, or component may be directly electrically connected to the another layer, region, or component, and/or indirectly electrically connected to the another layer, region, or component as intervening layer, region, or component is present.

In the specification, the terms “x-axis,” “y-axis,” and “z-axis” as used herein are not limited to three axes in an orthogonal coordinate system, and may be interpreted in a broader sense than the aforementioned three axes in an orthogonal coordinate system. For example, the x-axis, y-axis, and z-axis may describe axes that are orthogonal to each other, or may describe axes that are in different directions that are not orthogonal to each other.

In the present specification, when an illustrative embodiment is implemented differently, a specific process order may be performed differently from the described order. For example, two processes described in succession may be performed substantially simultaneously, or may be performed in an order opposite to the described order.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within ±30%, 20%, 10%, 5% of the stated value, for example.

Hereinafter, embodiments will be described in detail with reference to the accompanying drawings. The same or corresponding components will be denoted by the same reference numerals, and thus redundant description thereof will be omitted. Sizes of components in the drawings may be exaggerated for convenience of explanation. In other words, because sizes and thicknesses of components in the drawings are arbitrarily illustrated for convenience of explanation, the following the disclosure is not limited thereto.

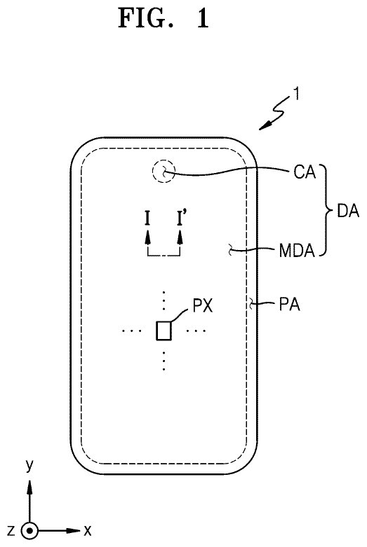

FIG. 1 is a plan view schematically showing an embodiment of a display apparatus 1.

The display apparatus 1 according to this embodiment may be an electronic device such as a smartphone, a mobile phone, a navigation device, game consoles, a television, a vehicle head unit, a notebook computer, a laptop computer, a tablet computer, a personal media player (“PMP”), or a personal digital assistant (“PDA”). Additionally, these electronic devices may be flexible devices.

As shown in FIG. 1, the display apparatus 1 may include a display area DA on which a plurality of pixels PX is arranged and a peripheral area PA disposed outside the display area DA. In an embodiment, the peripheral area PA may surround an entirety of the display area DA, for example.

Each pixel PX of the display apparatus 1 is an area that may emit light of a predetermined color, and the display apparatus 1 may provide an image by the light emitted from the pixels PX. In an embodiment, each pixel PX may emit red light, green light, or blue light, for example. To this end, a display element corresponding to each pixel PX may be disposed on the display area DA. That is, each display element may emit red light, green light, or blue light. In other words, the pixel PX may be implemented by the display element. In an embodiment, the display element may be various types of light-emitting elements, such as an organic light-emitting diode including an organic emission layer or a light-emitting diode including an inorganic emission layer, for example.

When the display area DA is viewed in a planar shape, the display area DA may have an approximately quadrangular shape, e.g., rectangular shape as shown in FIG. 1. However, the disclosure is not limited thereto, and the display area DA may have a polygonal shape such as a triangle, a pentagon, or a hexagon, a circular shape, an elliptical shape, or an irregular shape. Corners of the edges of the display area DA may have a round shape.

The peripheral area PA may be a non-display area on which pixels PX are not arranged. That is, display elements may not be arranged on the peripheral area PA. Drivers for providing electrical signals or power to display elements corresponding to pixels PX may be arranged on the peripheral area PA. On the peripheral area PA, a plurality of pads (not shown), which are areas to which electronic elements, printed circuit boards, or the like may be electrically connected, may be arranged. Each pad may be disposed spaced apart from each other on the peripheral area PA and may be electrically connected to a printed circuit board or an integrated circuit device.

The display area DA may include a main display area MDA and a component area CA. A main image may be displayed on the main display area MDA, and an auxiliary image may be displayed on the component area CA.

The main display area MDA may have a shape surrounding the component area CA. However, the disclosure is not limited thereto, and various modifications are possible, such as a part of the component area CA may contact the peripheral area PA. That is, the main display area MDA may at least partially surround the component area CA. The main display area MDA may occupy most area of the display area DA. Occupying most area of the display area DA may mean that the area of the main display area MDA is approximately 50% or more of the area of the display area DA. The component area CA may have a smaller area than that of the main display area MDA.

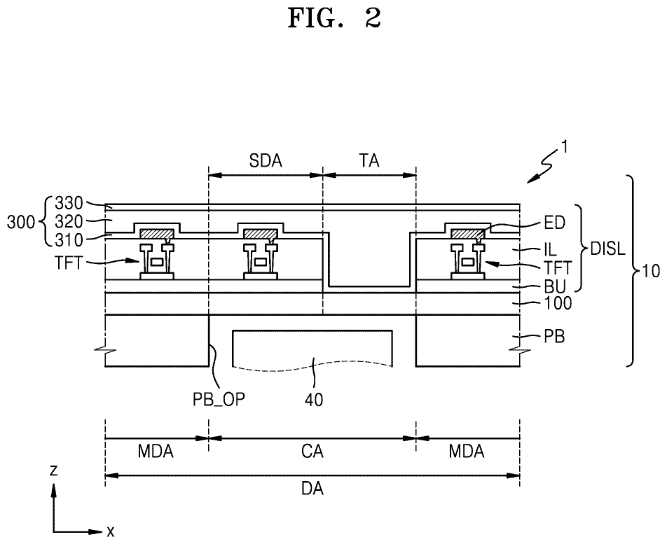

As will be described below with reference to FIG. 2, a component 40 (refer to FIG. 2), which is an electronic element, may be disposed under a display panel 10 corresponding to the component area CA. The component area CA may include a transmission area TA through which light and/or sound output from the component 40 to the outside or traveling from the outside toward the component 40 may transmit.

The component 40 may be an electronic element that uses light or sound. In an embodiment, electronic elements may include a proximity sensor that measures distance, a sensor that recognizes parts of a user's body (e.g., fingerprint, iris, face, etc.), a relatively small lamp that outputs light, an illuminance sensor that measures brightness, or an image sensor (e.g., camera) that captures an image, for example. Electronic elements that use light may use light in various wavelength bands, such as visible light, infrared light, or ultraviolet light. Electronic elements that use sound may use ultrasonic waves or sounds in other frequency bands. In some embodiments, the component 40 may include sub-components, such as a light-emitting unit and a light-receiving unit. The component 40 may include a light-emitting unit and a light-receiving unit which are integrated, or may include a pair of a light-emitting unit and a light-receiving unit in which the units are physically separated.

In the display apparatus 1 in an embodiment, when light is transmitted through the component area CA, the light transmittance may be about 10% or more, or about 20% or more, or about 30% or more, or about 40% or more, or about 50% or more, or about 60% or more, or about 70% or more, or about 75% or more, or about 80% or more, or about 85% or more, or about 90% or more.

When viewed from a direction (z-axis direction) approximately perpendicular to the upper surface of the display apparatus 1, the shape of the component area CA may be a polygonal shape such as a triangle, a square, a pentagon, or a hexagon, a circular shape, an elliptical shape, or a star shape, or an irregular shape. In FIG. 1, the display area DA is shown as including one component area CA. However, the disclosure is not limited thereto.

In another embodiment, the component area CA may include a plurality of sub-component areas spaced apart from each other. The sizes of the plurality of sub-component areas may be different from each other as desired. When the component area CA includes a plurality of sub-component areas, components 40 with different functions may be disposed respectively corresponding to the sub-component areas. In an embodiment, a camera may be disposed under the display panel 10 corresponding to a first sub-component area, an illuminance sensor may be disposed under the display panel 10 corresponding to a second sub-component area, and a proximity sensor may be disposed under the display panel 10 corresponding to a third sub-component area, for example.

FIG. 2 is a cross-sectional view schematically showing a part of the display apparatus of FIG. 1. As shown in FIG. 2, the display apparatus 1 may include a display panel 10 and a component 40 disposed to be overlapped with the display panel 10. That is, the component 40 may be disposed under the display panel 10 to correspond to the component area CA. In other words, when viewed from a direction (z-axis direction) approximately perpendicular to the display apparatus 1, the component area CA of the display panel 10 may be overlapped with the component 40.

The display panel 10 may include a substrate 100, a display layer DISL on the substrate 100, and a panel protection member PB disposed under the substrate 100.

The substrate 100 may include a polymer resin. The substrate 100 may include a polymer resin, such as a polyimide, a polyethersulfone, a polyacrylate, a polyetherimide, a polyethylene naphthalate, a polyethylene terephthalate, a polyphenylene sulfide, a polyarylate, a polycarbonate, or a cellulose acetate propionate. Accordingly, the display panel 10 may have flexible or bendable properties.

For the substrate 100, various modifications are possible, such as the substrate 100 may have a multi-layered structure, which includes two layers including such a polymer resin, and a barrier layer including an inorganic insulating material (silicon oxide (SiO_{X}), silicon nitride (SiN_{X}), or silicon oxynitride (SiO_{X}N_{Y})) between the two layers. More details on the materials included in the substrate 100 and the structure of the substrate will be described below.

The display layer DISL on the substrate 100 may include a pixel circuit including transistors TFT, a display element ED, and an encapsulation layer 300. FIG. 2 shows that the display layer DISL has a buffer layer BU, and a transistor TFT or the like is disposed on the buffer layer BU. The display element ED may be an organic light-emitting diode. The pixel circuit including transistors TFT may control whether or not the display element ED emits light or the degree of light emission. However, an insulating layer IL for insulation between a semiconductor layer, a gate electrode, and/or source/drain electrodes of the transistor TFT may also be included in the display layer DISL. Each of the buffer layer BU and the insulating layer IL may have a hole corresponding to the transmission area TA. This hole may expose a portion of the upper surface of the substrate 100.

The display element ED may be disposed not only on the main display area MDA but also in the component area CA. That is, the component area CA may include sub-display areas SDA and transmission areas TA, and display elements ED may be disposed on the sub-display areas SDA. The transmission area TA may be defined as an area in the component area CA on which display elements ED are not arranged. The transmission area TA may be an area through which light/signals emitted from the component 40 disposed corresponding to the component area CA or light/signals incident on the component 40 are transmitted. The transistor TFT electrically connected to the display element ED disposed on the component area CA may be disposed on the component area CA as shown in FIG. 2, or may be disposed on the main display area MDA, but may be electrically connected to the display element ED disposed on the component area CA through wiring or the like.

The display elements ED may be covered with an encapsulation layer 300 as shown in FIG. 2. In an alternative embodiment, the display elements ED may be covered with a sealing substrate. As shown in FIG. 2, the encapsulation layer 300 may include at least one inorganic encapsulation layer and at least one organic encapsulation layer. In an embodiment, the encapsulation layer 300 may include a first inorganic encapsulation layer 310, a second inorganic encapsulation layer 330, and an organic encapsulation layer 320 therebetween, for example.

The first inorganic encapsulation layer 310 and the second inorganic encapsulation layer 330 may include one or more inorganic insulating materials, such as silicon oxide (SiO_{X}), silicon nitride (SiNₓ), or silicon oxynitride (SiOₓN_{y}), and may be formed by a chemical vapor deposition (“CVD”) method or the like. The organic encapsulation layer 320 may include polymer-based materials. The polymer-based materials may include a silicone-based resin, an acrylic resin (e.g., a polymethyl methacrylate, a polyacrylic acid, etc.), an epoxy-based resin, a polyimide, and a polyethylene.

Each of the first inorganic encapsulation layer 310, the organic encapsulation layer 320, and the second inorganic encapsulation layer 330 may be unitary to cover the main display area MDA and the component area CA. As described above, a portion of the upper surface of the substrate 100 is exposed by the hole of the insulating layer IL corresponding to the transmission area TA, and thus, a portion of the encapsulation layer 300 may be in a direct contact with the substrate 100.

The panel protection member PB may be attached under the substrate 100 and act to support and protect the substrate 100. The panel protection member PB may define an opening PB_OP corresponding to the component area CA. By making the panel protection member PB defining an opening PB_OP, the light transmittance of the component area CA may be improved. The panel protection member PB may include a polyethyleneterephthalate or a polyimide.

The area of the component area CA may be larger than the area on which the component 40 is disposed. Accordingly, the area of the opening PB_OP provided on the panel protection member PB may not match the area of the component area CA. In FIG. 2, at least a portion of the component 40 is shown as being inserted into the opening PB_OP provided on the panel protection member PB, but the component 40 may also be disposed spaced apart from the display panel 10.

In an embodiment, although not shown, the display panel 10 may further include a bottom metal layer between the substrate 100 and the buffer layer BU. The bottom metal layer may be disposed overlapped with pixel circuits to protect the pixel circuits.

Specifically, the bottom metal layer may be disposed under a pixel circuit including a transistor TFT. This bottom metal layer may prevent or minimize light from reaching and affecting the pixel circuit. The bottom metal layer may be disposed only in the component area CA or may also be disposed on the main display area MDA. The bottom metal layer disposed on the component area CA may define an opening corresponding to the transmission area TA.

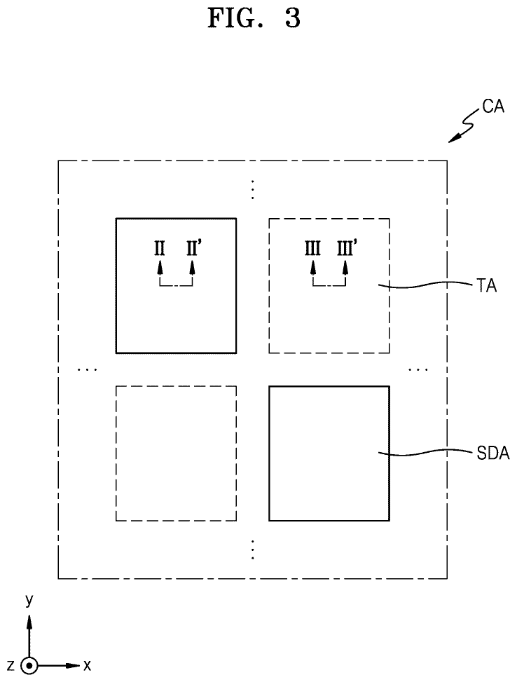

FIG. 3 is a plan view schematically showing an embodiment of a part of a component area CA of a display apparatus 1.

As described above, the component area CA may include a sub-display area SDA and a transmission area TA. A plurality of sub-display areas SDA may be provided, and a plurality of transmission areas TA may be provided. In FIG. 3, for convenience of illustration, the sub-display area SDA and the transmission area TA are shown to be spaced apart from each other, however, the disclosure is not limited thereto. The sub-display area SDA and the transmission area TA may be arranged so that one side of the sub-display area SDA and one side of the transmission area TA contact each other.

A plurality of sub-display areas SDA may be arranged spaced apart from each other. Transmission areas TA may be disposed between the plurality of sub-display areas SDA. In an alternative embodiment, each sub-display area SDA may be surrounded by transmission areas TA. In an embodiment, as shown in FIG. 3, the sub-display areas SDA and transmission areas TA may be alternately arranged, for example. Specifically, the sub-display areas SDA and the transmission areas TA may be alternately arranged along a first direction (e.g., x-axis direction) and alternately arranged along a second direction (e.g., y-axis direction).

That is, only two sub-display areas SDA and two transmission areas TA are shown in FIG. 3, but the sub-display area SDA and the transmission area TA may be repeatedly arranged along the first direction (e.g., x-axis direction) and the second direction (e.g., y-axis direction). Accordingly, the sub-display areas SDA and transmission areas TA may be alternately arranged along the first direction (e.g., x-axis direction) and alternately arranged along the second direction (e.g., y-axis direction).

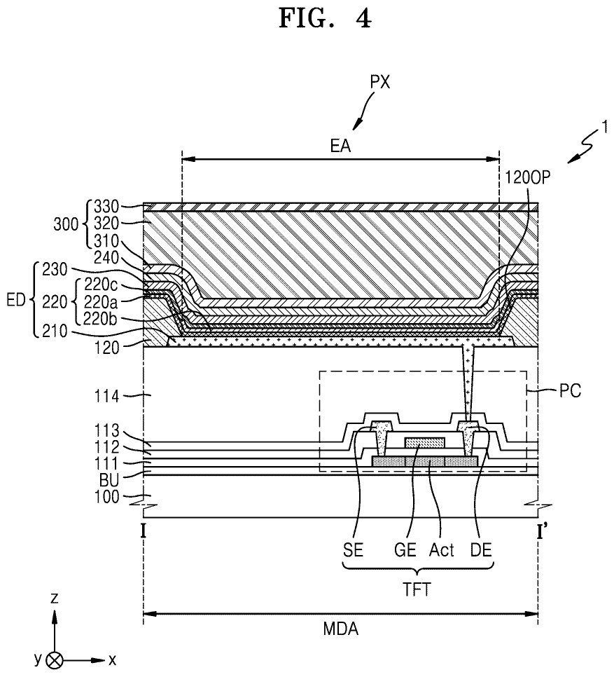

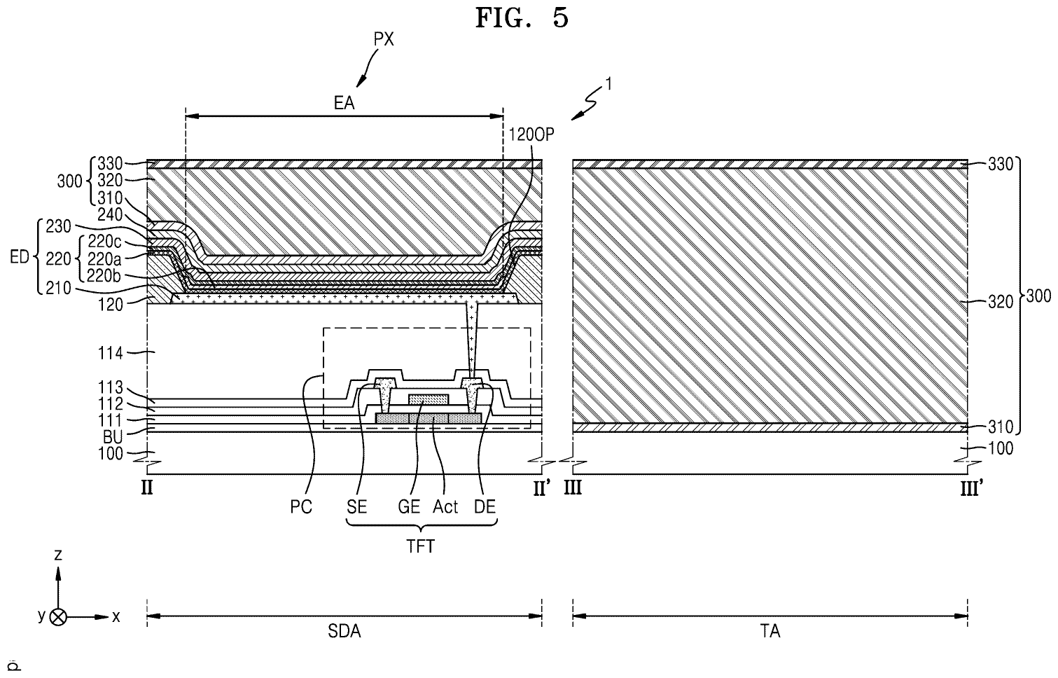

FIG. 4 is a cross-sectional view schematically showing a cross section taken along line I-I′ of the display apparatus 1 of FIG. 1. FIG. 5 is a cross-sectional view schematically showing a cross section taken along lines II-II′ and III-III′ of the display apparatus 1 of FIG. 3. Specifically, FIG. 4 is a cross-sectional view schematically showing a part of the main display area MDA of the display apparatus 1, and FIG. 5 is a cross-sectional view schematically showing a part of the component area CA of the display apparatus 1. In FIGS. 4 and 5, a panel protection member PB and a component 40 are omitted for convenience of illustration.

Referring to FIGS. 4 and 5, the display apparatus 1 may include a substrate 100. Specifically, the display apparatus 1 may include a display panel 10, and the display panel 10 may include a substrate 100. Since the display apparatus 1 may include the substrate 100, it may be said that the substrate 100 has the display area DA and the peripheral area PA as described above. Hereinafter, for convenience, the substrate 100 will be described as having a display area DA and a peripheral area PA. The display area DA of the substrate 100 may include a main display area MDA and a component area CA, and the component area CA may include a sub-display area SDA and a transmission area TA. A component 40 may be disposed under the component area CA of the substrate 100 to be overlapped with the component area CA of the substrate 100.

A buffer layer BU may be disposed on the substrate 100. The buffer layer BU may prevent or minimize penetration of foreign substances, moisture, or external air from the lower part of the substrate 100. The buffer layer BU may include an inorganic insulating material, such as silicon oxide (SiO_{X}), silicon nitride (SiN_{X}), or silicon oxynitride (SiO_{X}N_{Y}), and may have a single-layered structure or a multi-layered structure including such an inorganic insulating material.

A pixel circuit PC may be disposed on the buffer layer BU. In an embodiment, a plurality of pixel circuits PC may be provided, and the pixel circuits PC may be arranged on the buffer layer BU to be overlapped with the main display area MDA and the sub-display areas SDA, for example. In other words, the pixel circuits PC may be arranged on the main display area MDA and sub-display areas SDA. That is, the pixel circuits PC may be arranged on the display area DA excluding the transmission area TA.

The pixel circuit PC may include a transistor TFT. The TFT may include a semiconductor layer Act, a gate electrode GE, a source electrode SE, and a drain electrode DE. A gate insulating layer 111 may be disposed between the semiconductor layer Act and the gate electrode GE, and a first inter-insulating layer 112 may be disposed between the gate electrode GE and the source electrode SE and between the gate electrode GE and the drain electrode DE. A second inter-insulating layer 113 may be disposed on the source electrode SE and the drain electrode DE.

The semiconductor layer Act may be disposed on the buffer layer BU. The semiconductor layer Act may include polysilicon. In an alternative embodiment, the semiconductor layer Act may include amorphous silicon, an oxide semiconductor, an organic semiconductor, or the like. In an embodiment, the semiconductor layer Act may include a channel region, and a source region and a drain region respectively arranged on opposite sides of the channel region.

The gate insulating layer 111 may be disposed on the semiconductor layer Act and the buffer layer BU, and the gate electrode GE may be disposed on the gate insulating layer 111. That is, the gate insulating layer 111 may be disposed between the semiconductor layer Act and the gate electrode GE, thereby ensuring insulation between the semiconductor layer Act and the gate electrode GE. The gate electrode GE may be overlapped with the channel area of the semiconductor layer Act. The gate electrode GE may include a low-resistance metal material. In an embodiment, the gate electrode GE may include a conductive material including molybdenum (Mo), aluminum (AI), copper (Cu), or titanium (Ti), and a single-layered or a multi-layered structure including such a conductive material.

The first inter-insulating layer 112 may be disposed on the gate electrode GE and the gate insulating layer 111, and the source electrode SE and drain electrode DE may be arranged on the first inter-insulating layer 112. Each of the source electrode SE and drain electrode DE may be connected to the semiconductor layer Act through contact holes defined on the gate insulating layer 111 and the first inter-insulating layer 112. At least one of the source electrode SE and the drain electrode DE may include a conductive material including molybdenum (Mo), aluminum (AI), copper (Cu), or titanium (Ti), and may have a single-layered or multi-layered structure including such a conductive material. In an embodiment, at least one of the source electrode SE and the drain electrode DE may have a multi-layered structure of Ti/Cu/Ti.

The second inter-insulating layer 113 may be disposed on the source electrode SE, the drain electrode DE, and the first inter-insulating layer 112. The gate insulating layer 111, the first inter-insulating layer 112, and the second inter-insulating layer 113 may include an inorganic insulating material, such as silicon oxide (SiO_{X}), silicon nitride (SiN_{X}), or silicon oxynitride (SiO_{X}N_{Y}), and may have a single-layered structure or a multi-layered structure including such an inorganic insulating material.

An organic insulating layer 114 may be disposed on the second inter-insulating layer 113. The organic insulating layer 114 may serve as a protective film covering the transistor TFT, and upper part of the organic insulating layer 114 may be flat. Accordingly, the organic insulating layer 114 may provide a flat upper surface so that a pixel electrode 210 of the display element ED may be formed flat.

This organic insulating layer 114 may include an organic insulating material. In an embodiment, the organic insulating layer 114 may include general purpose polymers, such as benzocyclobutene (“BCB”), hexamethyldisiloxane (“HMDSO”), polymethylmethacrylate (“PMMA”), and polystyrene (“PS”), polymer derivatives having phenolic groups, acrylic polymers, imide-based polymers, aryl ether-based polymers, amide-based polymers, fluorine-based polymers, p-xylene-based polymers, vinyl alcohol-based polymers, and blends thereof, for example. The organic insulating layer 114 may have a single-layered or multi-layered structure including the above-mentioned material.

A display element ED may be disposed on the organic insulating layer 114. Specifically, a plurality of display elements ED may be provided, and the display elements ED may be arranged on the organic insulating layer 114 to be overlapped with the main display area MDA and the sub-display areas SDA. In other words, display elements ED may be arranged on the main display area MDA and sub-display areas SDA. That is, some of the display elements ED may be arranged on the main display area MDA, and the others of the display elements ED may be arranged on the sub-display areas SDA. The display element ED may not be disposed on the transmission area TA.

The display element ED may be an organic light-emitting diode having the pixel electrode 210, a counter electrode 230, and an interlayer 220 disposed therebetween, for example. The display element ED may be electrically connected to the transistor TFT of the pixel circuit PC. The expression “the display element ED is electrically connected to the transistor TFT” may be understood that the pixel electrode 210 of the organic light-emitting diode is electrically connected to the transistor TFT. That is, the pixel electrode 210 may contact either the source electrode SE or the drain electrode DE through the contact holes defined on the second inter-insulating layer 113 and the organic insulating layer 114 to thereby be electrically connected to the transistor TFT.

The pixel electrode 210 may include conductive oxides, such as indium tin oxide (“ITO”), indium zinc oxide (“IZO”), zinc oxide (ZnO), indium oxide (In₂O₃), and indium gallium oxide (“IGO”), or aluminum zinc oxide (“AZO”). In another embodiment, the pixel electrode 210 may include a reflective film including silver (Ag), magnesium (Mg), aluminum (Al), platinum (Pt), palladium (Pd), gold (Au), nickel (Ni), neodymium (Nd), iridium (Ir), chromium (Cr), or compounds thereof. In another embodiment, the pixel electrode 210 may further include a film including or consisting of ITO, IZO, ZnO, or In₂O₃ on/under the above-mentioned reflective film. In an embodiment, the pixel electrode 210 may have a three-layered structure of ITO/Ag/ITO, for example.

A pixel defining layer 120 may be disposed on the organic insulating layer 114, and the pixel defining layer 120 may cover the edges of the pixel electrode 210. The pixel defining layer 120 may define a pixel opening 1200P, and the pixel opening 1200P may be overlapped with the pixel electrode 210. The pixel opening 1200P may define an emission area of light emitted from the display element ED. The pixel defining layer 120 may include an organic insulating material and/or an inorganic insulating material. In some embodiments, the pixel defining layer 120 may include a light-blocking material.

The interlayer 220 may be disposed on the pixel electrode 210 and the pixel defining layer 120. The interlayer 220 may include an emission layer 220b. The emission layer 220b may include an organic material including a fluorescent or phosphorescent material that emits red, green, or blue light. The emission layer 220b may be a low-molecular organic material or a high-molecular organic material, and a first functional layer 220a and a second functional layer 220c may be optionally further arranged under and on the emission layer 220b. The first functional layer 220a may include at least one hole transport layer (“HTL”) and hole injection layer (“HIL”), and the second functional layer 220c may include at least one electron transport layer (“ETL”) and electron injection layer (“EIL”).

This interlayer 220 may be formed by a screen printing method, an inkjet printing method, a laser induced thermal imaging (“LITI”) method, or the like. However, the interlayer 220 is not necessarily limited thereto, and may have various structures. The interlayer 220 may include a layer that is integrated over the plurality of pixel electrodes 210, or may include a layer patterned to correspond to each of the plurality of pixel electrodes 210.

A counter electrode 230 may be disposed on the interlayer 220. The counter electrode 230 may be formed integrally in the plurality of organic light-emitting diodes and may correspond to the plurality of pixel electrodes 210. This counter electrode 230 may include a transparent conductive layer including or consisting of ITO, In₂O₃, or IZO, and may also include a transflective film including a metal such as Al or Ag. In an embodiment, the counter electrode 230 may be a transflective film including Mg or Ag, for example.

A capping layer 240 may be disposed on the counter electrode 230. In an embodiment, the capping layer 240 may include a material selected from an organic material, an inorganic material, and any combinations thereof, and may be provided as a single layer or multiple layers, for example. In an alternative embodiment, a LiF layer may be disposed on the capping layer 240.

Since these display elements ED may be easily damaged by moisture or oxygen from the outside, the display elements ED may be covered and protected with the encapsulation layer 300. The encapsulation layer 300 may include a first inorganic encapsulation layer 310, an organic encapsulation layer 320, and a second inorganic encapsulation layer 330, as shown in FIG. 4.

The first inorganic encapsulation layer 310 may cover the counter electrode 230 and may include silicon oxide (SiO_{X}), silicon nitride (SiN_{X}), and/or silicon oxynitride (SiO_{X}N_{Y}). This first inorganic encapsulation layer 310 may be formed along the structure thereunder, and thus, the upper surface thereof may not be flat as shown in FIG. 4. The organic encapsulation layer 320 may cover the first inorganic encapsulation layer 310 and the upper surface thereof may be substantially flat unlike the first inorganic encapsulation layer 310. This organic encapsulation layer 320 may include one or more material selected from the group consisting of a polyethyleneterephthalate, a polyethylenenaphthalate, a polycarbonate, a polyimide, a polyethylenesulfonate, a polyoxymethylene, a polyarylate, and a hexamethyldisiloxane. The second inorganic encapsulation layer 330 may cover the organic encapsulation layer 320 and may include silicon oxide (SiO_{X}), silicon nitride (SiN_{X}), and/or silicon oxynitride (SiO_{X}N_{Y}).

As such, the encapsulation layer 300 may include a first inorganic encapsulation layer 310, an organic encapsulation layer 320, and a second inorganic encapsulation layer 330, and, thus, due to this multi-layered structure, although cracks occur within the encapsulation layer 300, it is possible to prevent such cracks from being connecting between the first inorganic encapsulation layer 310 and the organic encapsulation layer 320 or between the organic encapsulation layer 320 and the second inorganic encapsulation layer 330. Through this, it is possible to prevent or minimize the formation of a path through which moisture or oxygen from the outside penetrates into the display panel 10.

As shown in FIG. 5, in the transmission area TA, the first inorganic encapsulation layer 310 of the encapsulation layer 300 may be disposed immediately on the substrate 100. In the transmission area TA, the first inorganic encapsulation layer 310 of the encapsulation layer 300 may be in direct contact with the substrate 100. That is, the layers arranged between the substrate 100 and the encapsulation layer 300 may be formed over the entirety of the surface of the substrate 100, but may not be formed on the transmission area TA. In other words, the layers arranged between the substrate 100 and the encapsulation layer 300 may have a shape corresponding to the entirety of the surface of the substrate 100, but portions corresponding to the transmission area TA of these layers may be removed.

In an embodiment, a buffer layer BU, a gate insulating layer 111, a first inter-insulating layer 112, a second inter-insulating layer 113, an organic insulating layer 114, a pixel defining layer 120, a first functional layer 220a, a second functional layer 220c, a counter electrode 230, and a capping layer 240 may not exist on the transmission area TA. That is, each of the buffer layer BU, the gate insulating layer 111, the first inter-insulating layer 112, the second inter-insulating layer 113, the organic insulating layer 114, the pixel defining layer 120, the first functional layer 220a, the second functional layer 220c, the counter electrode 230, and the capping layer 240 may have holes corresponding to the transmission area TA, for example. Accordingly, it is possible to prevent or minimize light output from the component 40 to the outside or traveling from the outside toward the component 40 from being reduced or changed.

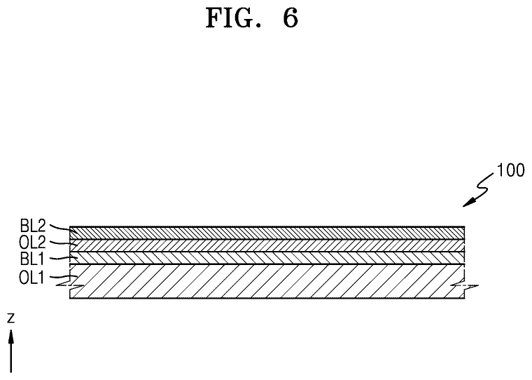

FIG. 6 is a cross-sectional view schematically showing the substrate 100 of FIGS. 4 and 5. As described above, the substrate 100 may have a multi-layered structure including two layers including a polymer resin and a barrier layer disposed between the two layers, the barrier layer including an inorganic insulating material (silicon oxide (SiO_{X}), silicon nitride (SiN_{X}), or silicon oxynitride (SiO_{X}N_{Y})). Specifically, as shown in FIG. 6, the substrate 100 may include a first organic layer OL1, a first barrier layer BL1, a second organic layer OL2, and a second barrier layer BL2.

Each of the first organic layer OL1 and the second organic layer OL2 may include a polymer resin. In an embodiment, each of the first organic layer OL1 and the second organic layer OL2 may include a polyimide. The first organic layer OL1 and the second organic layer OL2 may be manufactured from the same or similar materials through the same or similar processes. Accordingly, the materials included in the first organic layer OL1 and the materials included in the second organic layer OL2 may be the same or similar. Additionally, the properties (such as, optical properties or heat resistance properties) of the first organic layer OL1 may be the same or similar to the properties of the second organic layer OL2. Hereinafter, therefore, for convenience, the descriptions will be focused on the materials included in the first organic layer OL1 and the properties of the first organic layer OL1. However, details on the materials included in the first organic layer OL1 and the properties of the first organic layer OL1, which will be described below, may also be applied to the materials included in the second organic layer OL2 and the properties of the second organic layer OL2.

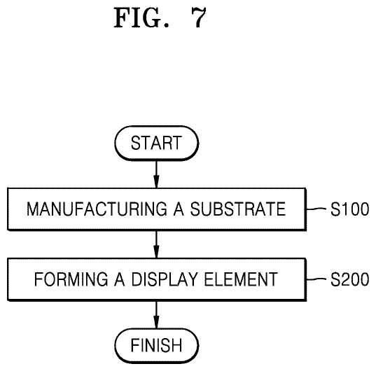

Specifically, as will be described below with reference to FIGS. 7 to 9, the first organic layer OL may be manufactured by curing polyamic acid prepared by polymerizing a dianhydride compound and a diamine compound. The dianhydride compound may include an oxydiphthalic anhydride and a biphenyl-tetracarboxylic acid dianhydride (“BPDA”), and the diamine compound may include a 4-aminophenyl-4-aminobenzoate (“APAB”), a 4,4′-oxydianiline (“ODA”), and a p-phenylenediamine (“PPD”). The oxidiphthalic anhydride may be a compound represented by Formula 1, and the BPDA may be a compound represented by Formula 2. The APAB may be a compound represented by Formula 3, the ODA may be a compound represented by Formula 4, and the PPD may be a compound represented by Formula 5:

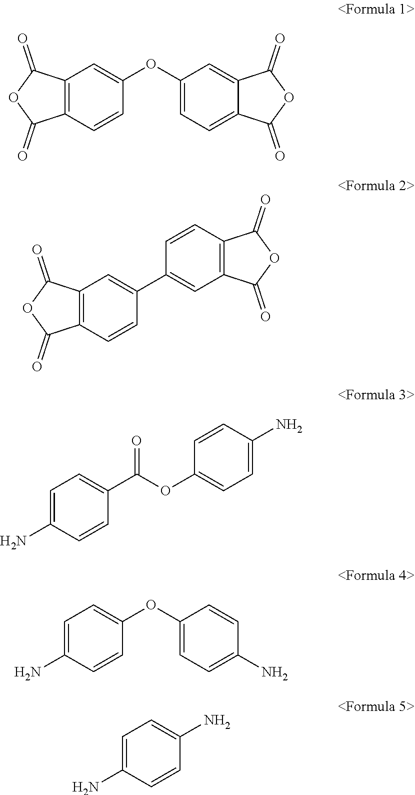

Specifically, the first organic layer OL1 may include a cured product of polyamic acid prepared by polymerizing an oxydiphthalic anhydride, a BPDA, an APAB, an ODA, and a PPD. That is, the polyamic acid for manufacturing the first organic layer OL1 may be a copolymer obtained by polymerizing an oxydiphthalic anhydride, a BPDA, an APAB, an ODA, and a PPD.

A molar ratio of the dianhydride compound and the diamine compound may be 1:1. That is, a ratio of a total mole number of the dianhydride compound and a total mole number of the diamine compound may be 1:1. The total mole number of the dianhydride compound may be the sum of mole numbers of each of compounds having two anhydride groups, and the total mole number of the diamine compound may be the sum of mole numbers of each of compounds having two amine groups.

When the dianhydride compound includes an oxydiphthalic anhydride and a BPDA, the total mole number of the dianhydride compound may be the sum of a mole number of the oxydiphthalic anhydride and a mole number of the BPDA. When the diamine compound includes an APAB, an ODA, and a PPD, the total mole number of the diamine compound may be the sum of a mole number of the APAB, a mole number of the ODA, and a mole number of the PPD.

When the mole number of the oxydiphthalic anhydride is expressed as “a” and the mole number of the BPDA is expressed as “b,” the mole number of the oxydiphthalic anhydride and the mole number of the BPDA may satisfy Equation 1 and Equation 2:

$$0.1 \leq \frac{a}{a + b} \leq 0.5 \qquad 〈 Equation 1 〉$$

$$0.5 \leq \frac{b}{a + b} \leq 0.9 \qquad 〈 Equation 2 〉$$

That is, the oxydiphthalic anhydride may be included in an amount of about 10 mol % to about 50 mol %, based on the total mole number of the dianhydride compound, and the BPDA may be included in an amount of about 50 mol % to about 90 mol %, based on the total mole number of the dianhydride compound.

When the mole number of the APAB is expressed as “c,” the mole number of the ODA is expressed as “d,” and the mole number of the PPD is expressed as “e,” the mole number of the APAB, the mole number of the ODA, and the mole number of the PPD may satisfy Formula 3, Formula 4, and Formula 5:

$$0.1 \leq \frac{c}{c + d + e} \leq 0.3 \qquad 〈 Equation 3 〉$$

$$0.1 \leq \frac{d}{c + d + e} \leq 0.3 \qquad 〈 Equation 4 〉$$

$$0.4 \leq \frac{e}{c + d + e} \leq 0.8 \qquad 〈 Equation 5 〉$$

That is, the APAB may be included in an amount of about 10 mol % to about 30 mol %, based on the total mole number of the diamine compound, the ODA may be included in an amount of about 10 mol % to about 30 mol %, based on the total mole number of the diamine compound, and the PPD may be included in an amount of about 40 mol % to about 80 mol %, based on the total mole number of the diamine compound.

As will be described below, when the mole number of the oxydiphthalic anhydride, the mole number of the BPDA, the mole number of the APAB, the mole number of the ODA, and the mole number of the PPD for preparing polyamic acid satisfies the ranges above, the packing of polyimide molecules included in the first organic layer OL1 may be not accomplished well, so the transmittance of the first organic layer OL1 at a short wavelength (e.g., a wavelength of about 400 nanometers (nm) to about 500 nm) may increase, and the heat resistance and mechanical properties of the first organic layer OL1 may not deteriorate.

In an embodiment, a transmittance of the first organic layer OL1 at a wavelength of 450 nm may be 80% or more. That is, the substrate 100 may have relatively high transparency. As the first organic layer OL1 has a transmittance of more than 80% at a wavelength of 450 nm, it is possible to minimize the reduction or change of light output from the component 40 to the outside or traveling from the outside toward the component 40 in the component area CA of the substrate 100. In an embodiment, a transmittance of the second organic layer OL2 at 450 nm may be 80% or more. In other words, a transmittance of each of the first organic layer OL1 and the second organic layer OL2 at 450 nm may be 80% or more.

In an embodiment, a coefficient of thermal expansion (“CTE”) of the first organic layer OL1 may be less than 12 parts-per-million per degree Celsius (ppm/° C.). As the first organic layer OL1 has a CTE of less than 12 ppm/° C., the first organic layer OL1 may have dimensional stability even under relatively high temperature conditions. In an embodiment, a CTE of the second organic layer OL2 may be less than 12 ppm/° C. In other words, a CTE of each of the first organic layer OL1 and the second organic layer OL2 may be less than 12 ppm/° C.

In an embodiment, a thermal decomposition temperature of the first organic layer OL1 may be greater than 500 degrees Celsius (° C.). As the first organic layer OL1 has a thermal decomposition temperature of greater than 500° C., the first organic layer OL1 may have relatively high stability and reliability under relatively high temperature conditions. In an embodiment, a thermal decomposition temperature of the second organic layer OL2 may be greater than 500° C. In other words, a thermal decomposition temperature of each of the first organic layer OL1 and the second organic layer OL2 may be greater than 500° C.

A first barrier layer BL1 may be disposed between the first organic layer OL1 and the second organic layer OL2. Specifically, the first barrier layer BL1 may be disposed on the first organic layer OL1, and the second organic layer OL2 may be disposed on the first barrier layer BL1. The first barrier layer BL1 may prevent external foreign substances from penetrating into the display apparatus 1.

The first barrier layer BL1 may include at least one of silicon oxide (SiO_{X}), silicon nitride (SiN_{X}), and silicon oxynitride (SiO_{X}N_{Y}). The first barrier layer BL1 may be a single layer or a multilayer including the above-mentioned materials. In an embodiment, the first barrier layer BL1 may be a multilayer, and may include a first-1 barrier layer including silicon oxynitride (SiO_{X}N_{Y}) and a first-2 barrier layer including silicon oxide (SiO_{X}), for example. In this case, the first-1 barrier layer may be disposed on the first organic layer OL1, and the first-2 barrier layer may be disposed on the first-1 barrier layer.

, the first barrier layer BL1 may be in direct contact with the second organic layer OL2. The second organic layer OL2 may be manufactured by a manufacturing method that will be described below with reference to FIGS. 7 to 9, and accordingly, the second organic layer OL2 may have sufficient adhesive strength to bond to the first barrier layer BL1. Therefore, a separate adhesive layer may not be disposed between the first barrier layer BL1 and the second organic layer OL2. Accordingly, the first barrier layer BL1 may be in direct contact with the second organic layer OL2. As there is no separate adhesive layer between the first barrier layer BL1 and the second organic layer OL2, it is possible to prevent or minimize light output from the component 40 to the outside or traveling from the outside toward the component 40 from being reduced or changed. That is, the substrate 100 may have relatively high transparency. As there is no separate adhesive layer between the first organic layer OL1 and the first barrier layer BL1, the first barrier layer BL1 may be in direct contact with the first organic layer OL1.

A second barrier layer BL2 may be disposed on the second organic layer OL2. Like the first barrier layer BL1, the second barrier layer BL2 may prevent external foreign substances from penetrating into the display apparatus 1.

The second barrier layer BL2 may include at least one of silicon oxide (SiO_{X}), silicon nitride (SiN_{X}), and silicon oxynitride (SiO_{X}N_{Y}). The second barrier layer BL2 may be a single layer or a multilayer including the above-mentioned materials. In an embodiment, the second barrier layer BL2 may be a multilayer, and may include a second-1 barrier layer including silicon oxide (SiO_{X}) and silicon oxynitride (SiO_{X}N_{Y}) and a second-2 barrier layer including silicon oxide (SiO_{X}), for example. In this case, the second-1 barrier layer may be disposed on the second organic layer OL2, and the second-2 barrier layer may be disposed on the second-1 barrier layer. In another embodiment, the second barrier layer BL2 may be a single layer including silicon oxide (SiO_{X}). As there is no separate adhesive layer between the second organic layer OL2 and the second barrier layer BL2, the second barrier layer BL2 may be in direct contact with the second organic layer OL2.

FIG. 7 is a flowchart illustrating an embodiment of a part of a method of manufacturing a display apparatus. Specifically, FIG. 7 is a flowchart illustrating the process of manufacturing the display apparatus 1 described above with reference to FIGS. 1 to 6. That is, the first organic layer OL1 or the second organic layer OL2 of the display apparatus 1 described above with reference to FIGS. 1 to 6 may correspond to the organic layer in the method of manufacturing the display apparatus in an embodiment. In FIG. 7, the same reference numerals as those in FIGS. 1 to 6 indicate the same members, and thus, redundant descriptions will be omitted.

Referring to FIG. 7, a method of manufacturing a display apparatus in an embodiment may include manufacturing a substrate (operation S100) and forming a display element (operation S200).

In the manufacturing a substrate (operation S100), a substrate 100 including the first organic layer OL1, the first barrier layer BL1, the second organic layer OL2, and the second barrier layer BL2 described above with reference to FIG. 6 may be manufactured. This substrate 100 may include a display area DA and a peripheral area PA as described above. The display area DA may include a main display area MDA and a component area CA, and the component area CA may include a sub-display area SDA and a transmission area TA.

Next, in the forming the display element ED (operation S200), the display element ED may be formed on the substrate 100. Specifically, display elements ED may be formed on a main display area MDA and sub-display areas SDA. That is, some of the plurality of display elements ED formed on the substrate 100 may be formed on the main display area MDA, and the others of the plurality of display elements ED formed on the substrate 100 may be formed on the sub-display areas SDA. The display element ED may not be formed on a transmission area TA.

Specifically, a transistor TFT included in a pixel circuit PC may be formed on the substrate 100. Before forming the display element ED on the substrate 100, a buffer layer BU may be formed on the substrate 100, a semiconductor layer Act may be formed on the buffer layer BU, a gate insulating layer 111 may be formed on the semiconductor layer Act, and a gate electrode GE may be formed on the gate insulating layer 111. A first inter-insulating layer 112 may be formed on the gate electrode GE, a source electrode SE and a drain electrode DE may be formed on the first inter-insulating layer 112, a second inter-insulating layer 113 may be formed on the source electrode SE and the drain electrode DE, and an organic insulating layer 114 may be formed on the second inter-insulating layer 113.

Next, the display element ED may be formed on an organic insulating layer 114. To this end, a pixel electrode 210 and a pixel defining layer 120 may be formed on the organic insulating layer 114, an interlayer 220 may be formed on the pixel electrode 210, and a counter electrode 230 may be formed on the interlayer 220. As this formation of the pixel circuit PC and the display element ED may be accomplished through known photo processes, detailed descriptions thereof will be omitted.

A capping layer 240 may be formed on the counter electrode 230, and an encapsulation layer 300 may be formed on the capping layer 240, the encapsulation layer 300 including a first inorganic encapsulation layer 310, an organic encapsulation layer 320, and a second inorganic encapsulation layer 330. As this formation of the capping layer 240 and the encapsulation layer 300 may be accomplished through a known photo process, a detailed description thereof will be omitted.

Although not shown in FIG. 7, the method of manufacturing a display apparatus according to this embodiment may further include forming a component 40 under a component area CA to be overlapped with the component area CA of the substrate 100. Accordingly, the manufactured display apparatus 1 may output light to the outside, or detect or recognize an external object or user by the component 40.

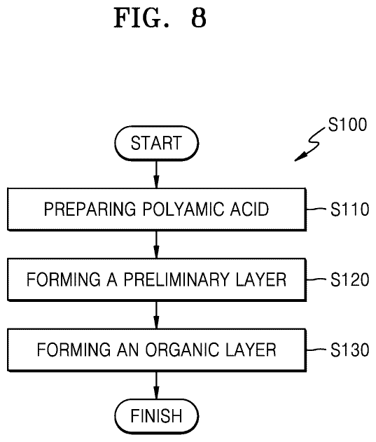

FIG. 8 is a flowchart illustrating an embodiment of a part of a method of manufacturing a display apparatus. Specifically, FIG. 8 is a flowchart illustrating a method of manufacturing a portion of the substrate 100 of FIG. 6. That is, FIG. 8 is a flowchart illustrating a method of manufacturing the first organic layer OL1 or the second organic layer OL2 of the substrate 100 of FIG. 6. In other words, FIG. 8 is a flowchart illustrating a part of the manufacturing a substrate (operation S100) of FIG. 7.

Referring to FIG. 8, a method of manufacturing a display apparatus 1 in an embodiment may include preparing polyamic acid (operation S110), forming a preliminary organic layer (operation S120), and forming an organic layer (operation S130).

In the preparing polyamic acid (operation S110), the polyamic acid may be prepared by polymerizing a dianhydride compound and a diamine compound. The dianhydride compound may include an oxydiphthalic anhydride and a BPDA, and the APAB, an ODA, and a PPD. The oxidiphthalic anhydride may be a compound represented by Formula 1, and the BPDA may be a compound represented by Formula 2. The APAB may be a compound represented by Formula 3, the ODA may be a compound represented by Formula 4, and the PPD may be a compound represented by Formula 5:

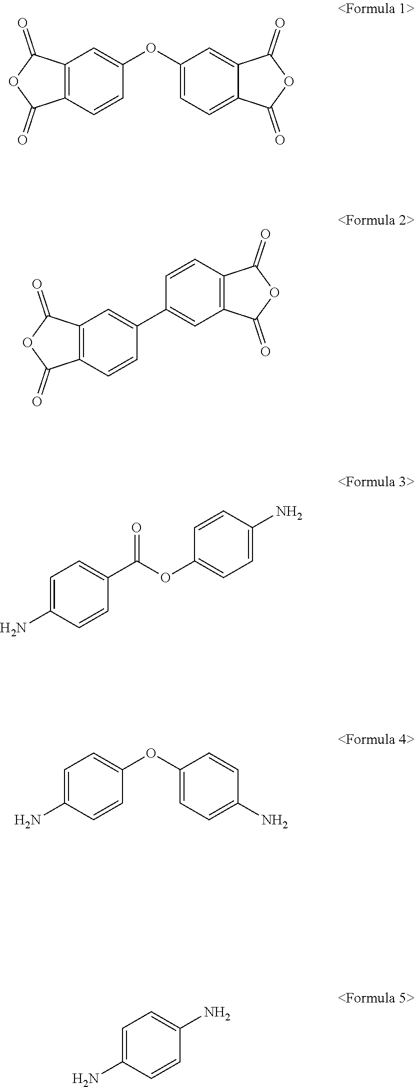 [SMILES: O=C1OC(=O)c2cc(Oc3ccc4c(c3)C(=O)OC4=O)ccc21 ; O=C1OC(=O)c2cc(-c3ccc4c(c3)C(=O)OC4=O)ccc21 ; Nc1ccc(OC(=O)c2ccc(N)cc2)cc1 ; Nc1ccc(Oc2ccc(N)cc2)cc1 ; Nc1ccc(N)cc1]

Specifically, the polyamic acid may be prepared by polymerizing an oxydiphthalic anhydride, a BPDA, an APAB, an ODA, and a PPD. That is, the polyamic acid may be a copolymer obtained by polymerizing an oxydiphthalic anhydride, a BPDA, an APAB, an ODA, and a PPD.

A molar ratio of the dianhydride compound and the diamine compound may be 1:1. That is, a ratio of a total mole number of the dianhydride compound and a total mole number of the diamine compound may be 1:1. The total mole number of the dianhydride compound may be the sum of mole numbers of each of compounds having two anhydride groups, and the total mole number of the diamine compound may be the sum of mole numbers of each of compounds having two amine groups.

When the dianhydride compound includes an oxydiphthalic anhydride and a BPDA, the total mole number of the dianhydride compound may be the sum of a mole number of the oxydiphthalic anhydride and a mole number of the BPDA. When the diamine compound includes an APAB, an ODA, and a PPD, the total mole number of the diamine compound may be the sum of a mole number of the APAB, a mole number of the ODA, and a mole number of the PPD.

When the mole number of the oxydiphthalic anhydride is expressed as “a” and the mole number of the BPDA is expressed as “b,” the mole number of the oxydiphthalic anhydride and the mole number of the BPDA may satisfy Equation 1 and Equation 2:

$$0.1 \leq \frac{a}{a + b} \leq 0.5 \qquad 〈 Equation 1 〉$$

$$0.5 \leq \frac{b}{a + b} \leq 0.9 \qquad 〈 Equation 2 〉$$

That is, the oxydiphthalic anhydride may be included in an amount of about 10 mol % to about 50 mol %, based on the total mole number of the dianhydride compound, and the BPDA may be included in an amount of about 50 mol % to about 90 mol %, based on the total mole number of the dianhydride compound.

When the mole number of the APAB is expressed as “c,” the mole number of the ODA is expressed as “d,” and the mole number of the PPD is expressed as “e,” the mole number of the APAB, the mole number of the ODA, and the mole number of the PPD may satisfy Formula 3, Formula 4, and Formula 5:

$$0.1 \leq \frac{c}{c + d + e} \leq 0.3 \qquad 〈 Equation 3 〉$$

$$0.1 \leq \frac{d}{c + d + e} \leq 0.3 \qquad 〈 Equation 4 〉$$

$$0.4 \leq \frac{e}{c + d + e} \leq 0.8 . \qquad 〈 Equation 5 〉$$

That is, the APAB may be included in an amount of about 10 mol % to about 30 mol %, based on the total mole number of the diamine compound, the ODA may be included in an amount of about 10 mol % to about 30 mol %, based on the total mole number of the diamine compound, and the PPD may be included in an amount of about 40 mol % to about 80 mol %, based on the total mole number of the diamine compound.

In general, when the packing of polyimide molecules in the organic layer are accomplished well, a transmittance of the organic layer at a short wavelength (e.g., a wavelength of about 400 nm to about 500 nm) may be low. That is, the transparency of the organic layer may be low. The transmittance of the organic layer at a short wavelength may be improved by introducing a bent structure into the chains of polyimide molecules included in the organic layer. That is, when a bent structure is introduced into the chains of polyimide molecules included in the organic layer, the packing of the polyimide molecules included in the organic layer may not be made well. Accordingly, the transmittance of this organic layer at a short wavelength may be increased. That is, this organic layer may have relatively high transparency. Accordingly, this organic layer may be used for purposes such as a substrate for a display apparatus requiring transparency. However, when a bent structure is excessively introduced into the chains of polyimide molecules included in the organic layer, the heat resistance and mechanical properties of the organic layer may deteriorate.

For the organic layer manufactured according to this embodiment, a bent structure may be introduced into the chains of polyimide molecules included in the manufactured organic layer. That is, oxydiphthalic anhydride, an APAB, and an ODA may cause a bent structure to be introduced into the chains of polyimide molecules included in the manufactured organic layer. When the mole number of the oxydiphthalic anhydride, a mole number of BPDA, the mole number of the APAB, the mole number of the ODA, and the mole number of the PPD for preparing polyamic acid satisfies the ranges above, the packing of polyimide molecules included in the organic layer may not accomplished well, so the transmittance of the organic layer at a short wavelength may increase, and the heat resistance and mechanical properties of the organic layer may not deteriorate.

When the mole number of the oxydiphthalic anhydride, the mole number of the APAB, the mole number of the ODA for preparing polyamic acid are less than the ranges above, and the mole number of the BPDA and the mole number of the PPD are greater than the ranges above, the packing of polyimide molecules included in the organic layer may be accomplished well, and thus, the transmittance of the organic layer at a short wavelength may be low. The mole number of the oxydiphthalic anhydride, the mole number of the APAB, and the mole number of the ODA for preparing polyamic acid are greater than the ranges above, and the mole number of the BPDA and the mole number of the PPD are less than the ranges above, the heat resistance and mechanical properties of the organic layer may deteriorate.

The dianhydride compound and the diamine compound may be provided in an organic solvent, and a polymerization reaction may be performed in the organic solvent to prepare polyamic acid. The organic solvent may be an N-methyl-2-pyrrolidone (“NMP”), an N,N-dimethyl acetamide (“DMAc”), a dimethylformamide (“DMF”), an m-cresol, a tetrahydrofuran (“THF”), or a chloroform, or a mixed solvent thereof. In an embodiment, the organic solvent may be an NMP, for example. However, the organic solvent used in the preparing polyamic acid (operation S100) is not limited to the types of solvents described above, and any organic solvent that may dissolve the dianhydride compound and diamine compound may be used without limitation.

In an embodiment, an oxydiphthalic anhydride, a BPDA, an APAB, an ODA, and a PPD may be polymerized in an NMP to prepare polyamic acid, for example. The mole number of the oxydiphthalic anhydride and the mole number of the BPDA provided in the NMP may satisfy Equation 1 and Equation 2. The mole number of the APAB, the mole number of the ODA, and the mole number of the PPD provided in the NMP may satisfy Equation 3, Equation 4, and Equation 5. Polyamic acid may be prepared by condensation reactions between an oxydiphthalic anhydride or a BPDA and an APAB, an ODA, or a PPD.

In an embodiment, an oxydiphthalic anhydride and a BPDA may be dissolved in an NMP to prepare a dianhydride compound solution. Separately, an APAB, an ODA, and a PPD may be dissolved in an NMP to prepare a diamine compound solution. Thereafter, the dianhydride compound solution and the diamine compound solution may be mixed so that the molar ratio of the dianhydride compound and the diamine compound is 1:1, and a polymerization reaction may be allowed to occur to thereby prepare polyamic acid. In another embodiment, an oxydiphthalic anhydride, a BPDA, an APAB, an ODA, and a PPD may be mixed in one step and a polymerization reaction may be allowed to occur to thereby prepare polyamic acid.

The polyamic acid, which is a polymerization product prepared by a polymerization reaction, may be included in an organic solvent in an amount of about 5 wt % to about 80 wt %. In an embodiment, the prepared polyamic acid may be included in an organic solvent in a solid content of about 10 wt % to about 50 wt %. The number average molecular weight (Mn) of the prepared polyamic acid may be about 10,000 to about 1,000,000, for example.

Next, in the forming the preliminary organic layer (operation S120), the polyamic acid prepared in the preparing polyamic acid (operation S100) may be applied onto a manufacturing substrate to form a preliminary organic layer.

Specifically, the polyamic acid may be applied along with an organic solvent onto the manufacturing substrate. The organic solvent applied along with the polyamic acid onto the manufacturing substrate may be an organic solvent in which a polymerization reaction was performed when the polyamic acid was prepared in the preparing polyamic acid (operation S100). However, the disclosure is not limited thereto. The organic solvent applied along with the polyamic acid onto the manufacturing substrate may be a separate organic solvent from the organic solvent in which a polymerization reaction was performed when the polyamic acid was prepared in the preparing polyamic acid (operation S100) and which was removed from the polyamic acid. The separate organic solvent may be those added to and be capable of dissolving the prepared polyamic acid.

The method of applying the prepared polyamic acid onto a manufacturing substrate is not limited to any one method, and any method that may uniformly apply the polyamic acid onto the manufacturing substrate to form a thin layer with the prepared polyamic acid may be used without limitation. In an embodiment, the prepared polyamic acid may be applied onto a manufacturing substrate by an inkjet printing method or the like, for example.

The substrate on which the prepared polyamic acid is applied may be used without limitation as long as the substrate may serve as a support for forming a preliminary organic layer. In an embodiment, the manufacturing substrate may be a glass substrate, a substrate including or consisting of metal materials, or a substrate including or consisting of polymer materials, for example. The surface of the manufacturing substrate may have smoothness to ensure that the polyamic acid is uniformly applied. When manufacturing a second organic layer OL2, the manufacturing substrate may have the first organic layer OL1 and the second barrier layer BL2 formed on the manufacturing substrate. That is, when manufacturing the second organic layer OL2, the first organic layer OL1 and the second barrier layer BL2 may be formed on the manufacturing substrate before applying the polyamic acid onto the manufacturing substrate. However, the disclosure is not limited thereto.

As described above, polyamic acid may be applied along with an organic solvent onto a manufacturing substrate. That is, a solution in which polyamic acid is dissolved in an organic solvent may be applied onto a manufacturing substrate. Accordingly, an organic solvent along with polyamic acid may be applied onto a manufacturing substrate. In other words, an organic solvent along with polyamic acid may be provided on a manufacturing substrate. The polyamic acid applied along with the organic solvent may be dried to remove at least a portion of the organic solvent. The term “preliminary organic layer” as used herein may refer to a layer from which at least a portion of the organic solvent is removed by drying the polyamic acid applied with the organic solvent.

In an embodiment, the drying of the polyamic acid applied along with the organic solvent may be performed by a high vacuum chamber dry (“HVCD”) method. The HVCD method may include a first drying and a second drying. A manufacturing substrate coated with polyamic acid along with an organic solvent may be put into a chamber, and in the first drying, the polyamic acid applied with the organic solvent may be dried at 80° C. for 180 seconds. In the first drying, the pressure in the chamber may be decreased from normal pressure to 10 torr. In the second drying, the polyamic acid applied along with the organic solvent may be dried at 80° C. for 150 seconds. In the second drying, the pressure in the chamber may be decreased from about 10 torr to about 0.1 torr. Accordingly, the organic solvent applied along with the polyamic acid may be removed by about 60%, based on the amount of the organic solvent initially applied onto the manufacturing substrate.

Next, in the forming the organic layer (operation S130), the preliminary organic layer formed in the forming the preliminary organic layer (operation S120) may be heat treated to cure the preliminary organic layer. Accordingly, an organic layer may be formed. In the forming the organic layer (operation S130), the preliminary organic layer may be heat treated to subject the polyamic acid to the reaction by thermal imidization to thereby form polyimide. The term “organic layer” as used herein may refer to ‘a layer obtained by curing the preliminary organic layer to form polyimide through the reaction of the polyamic acid in the preliminary organic layer.’

In the forming the organic layer (operation S130), the preliminary organic layer may be heat treated at a temperature of about 50° C. to about 500° C. In an embodiment, the preliminary organic layer may be heat treated at a temperature of about 80° C. to about 470° C., for example. The preliminary organic layer may be heat treated for about 3 hours to about 4 hours. The forming the organic layer (operation S130) may include a plurality of heat treatments performed in the temperature ranges above. Specifically, the forming the organic layer (operation S130) may include a plurality of heat treatments, and each of these heat treatments may be performed at a temperature of about 80° C. to about 470° C. The total time for which these plurality of heat treatments are performed may be about 3 hours to about 4 hours.

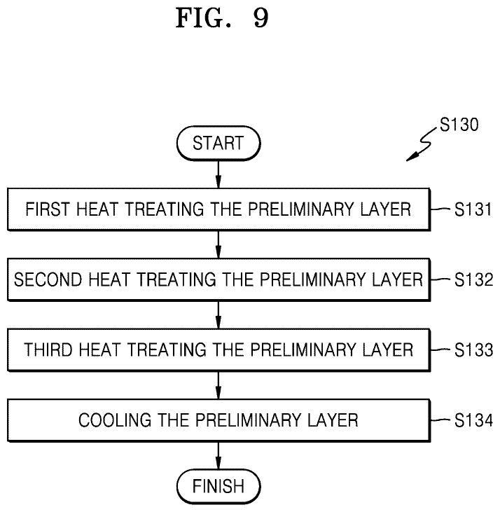

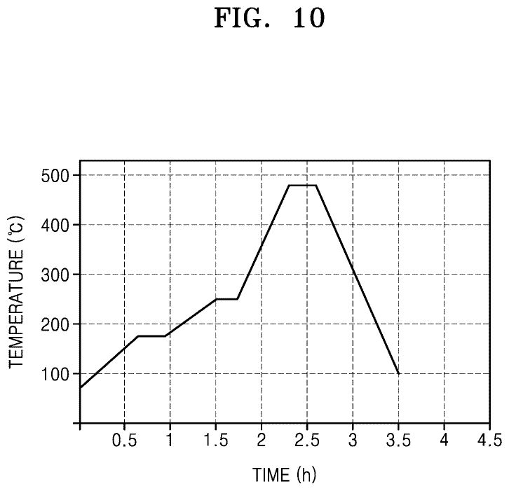

FIG. 9 is a flowchart illustrating an embodiment of a part of a method of manufacturing a display apparatus 1. Specifically, FIG. 9 is a flowchart illustrating the forming the organic layer (operation S130) of FIG. 8. FIG. 10 is a graph showing the temperature of the preliminary organic layer in the forming the organic layer (operation S130).

Referring to FIG. 9, the forming the organic layer (operation S130) may include first heat treating the preliminary organic layer (operation S131), second heat treating the preliminary organic layer (operation S132), third heat treating the preliminary organic layer (operation S133), and cooling the preliminary organic layer (operation S134).

In the first heat treating the preliminary organic layer (operation S131), the preliminary organic layer may be first heat treated to increase the temperature of the preliminary organic layer from a first temperature to a second temperature. The second temperature may be higher than the first temperature. Specifically, the temperature of the preliminary organic layer may be increased from the first temperature to the second temperature and the temperature of the preliminary organic layer may be maintained at the second temperature.

The first temperature may be 80° C., and the second temperature may be 180° C. The time desired to increase the temperature of the preliminary organic layer from the first temperature to the second temperature may be about 30 minutes to about 40 minutes. That is, a heating rate of the preliminary organic layer may be about 2.50 degrees Celsius per minute (° C./min) to about 3.33° C./min. When the heating rate of the preliminary organic layer in the first heat treating (operation S131) is about 2.50° C./min to about 3.33° C./min, the packing of the polyimide molecules formed by the reaction of the polyamic acid molecules included in the preliminary organic layer may not be accomplished well. Accordingly, the transmittance of the organic layer generated from this preliminary organic layer at a short wavelength (e.g., a wavelength of about 400 nm to about 500 nm) may be high. That is, this organic layer may have relatively high transparency.

When the packing of the polyimide molecules formed by the reaction of the polyamic acid molecules included in the preliminary organic layer is not accomplished well, the organic layer generated from this preliminary organic layer may have amorphous characteristics, thereby improving the adhesion with other layers. Therefore, when the heating rate of the preliminary organic layer in the first heat treating (operation S131) is about 2.50° C./min to about 3.33° C./min, the organic layer generated from the preliminary organic layer may have relatively high adhesion.

When the heating rate of the preliminary organic layer in the first heat treating (operation S131) is less than 2.50° C./min, the packing of the polyimide molecules formed by the reaction of the polyamic acid molecules included in the preliminary organic layer may be accomplished well. Accordingly, the transmittance of the organic layer generated from this preliminary organic layer at a short wavelength may be low. When the heating rate of the preliminary organic layer in the first heat treating (operation S131) is greater than 3.33° C./min, bubbles may be generated during the curing process of the preliminary organic layer, thereby causing defects. In an embodiment, these bubbles may be caused by by-products generated during the curing process of the preliminary organic layer, for example. However, the disclosure is not limited thereto.

In an embodiment, as shown in FIG. 10, in the first heat treating (operation S131), the temperature of the preliminary organic layer may be increased from about 80° C. to about 180° C. at a rate of 2.86° C./min for 35 minutes, and the temperature of the preliminary organic layer may be maintained at 180° C. for 15 minutes.

Next, in the second heat treating the preliminary organic layer (operation S132), the preliminary organic layer may be second heat treated to increase the temperature of the preliminary organic layer from the second temperature to a third temperature. The third temperature may be higher than the second temperature. Specifically, the temperature of the preliminary organic layer may be increased from the second temperature to the third temperature and the temperature of the preliminary organic layer may be maintained at the third temperature.

The second temperature may be 180° C. and the third temperature may be 250° C. The time desired to increase the temperature of the preliminary organic layer from the second temperature to the third temperature may be about 35 minutes to about 45 minutes. That is, the heating rate of the preliminary organic layer may be about 1.56° C./min to about 2.00° C./min.

Also in the second heat treating (operation S132), the reaction of polyamic acid molecules forming polyimide molecules continues. Therefore, like the heating rate of the preliminary organic layer in the first heat treating (operation S131), the heating rate of the preliminary organic layer in the second heat treating (operation S132) may affect the degree of packing of the polyimide molecules formed by the reaction of the polyamic acid molecules included in the preliminary organic layer. When the heating rate of the preliminary organic layer in the second heat treating (operation S132) is about 1.56° C./min to about 2.00° C./min, the packing of the polyimide molecules formed by the reaction of the polyamic acid molecules included in the preliminary organic layer may not be accomplished well. Accordingly, the transmittance of the organic layer generated from this preliminary organic layer at a short wavelength may be relatively high and the adhesion of this organic layer may also be high.

When the heating rate of the preliminary organic layer in the second heat treating (operation S132) is less than 1.56° C./min, the packing of the polyimide molecules formed by the reaction of the polyamic acid molecules included in the preliminary organic layer may be accomplished well. Accordingly, the transmittance of the organic layer generated from this preliminary organic layer at a short wavelength may be low. When the heating rate of the preliminary organic layer in the second heat treating (operation S132) is greater than 2.00° C./min, bubbles may be generated during the curing process of the preliminary organic layer, thereby causing defects.

In an embodiment, as shown in FIG. 10, in the second heat treating (operation S132), the temperature of the preliminary organic layer may be increased from about 180° C. to about 250° C. at a rate of 1.75° C./min for 40 minutes and the temperature of the preliminary organic layer may be maintained at 250° C. for 15 minutes.

Next, in the third heat treating the preliminary organic layer (operation S133), the preliminary organic layer may be third heat treated to increase the temperature of the preliminary organic layer from the third temperature to a fourth temperature. The fourth temperature may be higher than the third temperature. Specifically, the temperature of the preliminary organic layer may be increased from the third temperature to the fourth temperature and the temperature of the preliminary organic layer may be maintained at the fourth temperature.

The third temperature may be 250° C. and the fourth temperature may be 470° C. The time desired to increase the temperature of the preliminary organic layer from the third temperature to the fourth temperature may be about 27 minutes to about 37 minutes. That is, the heating rate of the preliminary organic layer may be about 5.95° C./min to about 8.15° C./min.

Also in the third heat treating (operation S133), the reaction of polyamic acid molecules forming polyimide molecules continues. Therefore, like the heating rate of the preliminary organic layer in the first heat treating (operation S131) and the heating rate of the preliminary organic layer in the second heat treating (operation S132), the heating rate of the preliminary organic layer in the third heat treating (operation S133) may affect the degree of packing of the polyimide molecules formed by the reaction of the polyamic acid molecules included in the preliminary organic layer. When the heating rate of the preliminary organic layer in the third heat treating (operation S133) is about 5.95° C./min to about 8.15° C./min, the packing of the polyimide molecules formed by the reaction of the polyamic acid molecules included in the preliminary organic layer may not be accomplished well. Accordingly, the transmittance of the organic layer generated from this preliminary organic layer at a short wavelength may be relatively high and the adhesion of this organic layer may also be high.

When the heating rate of the preliminary organic layer in the third heat treating (operation S133) is less than 5.95° C./min, the packing of the polyimide molecules formed by the reaction of the polyamic acid molecules included in the preliminary organic layer may be accomplished well. Accordingly, the transmittance of the organic layer generated from this preliminary organic layer at a short wavelength may be low. When the heating rate of the preliminary organic layer in the third heat treating (operation S133) is greater than 8.15° C./min, bubbles may be generated during the curing process of the preliminary organic layer, thereby causing defects.

In an embodiment, as shown in FIG. 10, in the third heat treating (operation S133), the temperature of the preliminary organic layer may be increased from about 250° C. to about 470° C. at a rate of 6.88° C./min for 32 minutes and the temperature of the preliminary organic layer is may be maintained at 470° C. for 23 minutes.

Next, in the cooling the preliminary organic layer (operation S134), the preliminary organic layer may be cooled to decrease the temperature of the preliminary organic layer from the fourth temperature to a fifth temperature. Accordingly, an organic layer may be formed. The fifth temperature may be lower than the fourth temperature. The fourth temperature may be 470° C. and the fifth temperature may be 100° C. The time desired to decrease the temperature of the preliminary organic layer from the fourth temperature to the fifth temperature may be about 40 minutes to about 60 minutes. In an embodiment, as shown in FIG. 10, in the cooling the preliminary organic layer (operation S134), the temperature of the preliminary organic layer may be decreased from about 470° C. to about 100° C. for 50 minutes.

Hereinafter, the organic layer manufactured according to the method of manufacturing a display apparatus in an embodiment will be described in detail, referring to Embodiments and Comparative Examples. The Embodiments described below is an illustrative embodiment to aid understanding of the disclosure, and the scope of the disclosure is not limited thereto.

### Embodiment 1

### 1. Preparation of Polyamic Acid

Polyamic acid was prepared through the following steps by condensation polymerization in a solution with the molar ratio of a dianhydride compound and a diamine compound at 1:1. The dianhydride compound included an oxydiphthalic anhydride and a BPDA, and the diamine compound included an APAB, an ODA, and a PPD. The oxydiphthalic anhydride was included in an amount of 10 mol % based on the total mole number of the dianhydride compound, and the BPDA was included in an amount of 90 mol % based on the total mole number of the dianhydride compound. The APAB was included in an amount of 10 mol % based on the total mole number of the diamine compound, the ODA was included in an amount of 10 mol % based on the total mole number of the diamine compound, and the PPD was included in an amount of 80 mol % based on the total mole number of the diamine compound.

An oxydiphthalic anhydride and a BPDA were added to a flask to which an NMP was added as an organic solvent so that the oxydiphthalic anhydride and the BPDA had the above-mentioned mole percentages, to thereby prepare 2 m (molality) of dianhydride compound solution. In addition, an APAB, an ODA, and a PPD were added to a separate flask to which an NMP was added as an organic solvent so that the APAB, the ODA, and the PPD had the above-mentioned mole percentages, to thereby prepare a 2 m diamine compound solution. Thereafter, the dianhydride compound solution was added to a flask including or consisting of the diamine compound solution and stirred at room temperature (25° C.) to relatively low temperature (−10° C.) to prepare a polyamic acid solution. At this time, the polyamic acid solution included about 20 wt % of polyamic acid, and the viscosity of the polyamic acid solution was about 4,000 centipoises (cP).

### 2. Formation of Preliminary Organic Layer

The polyamic acid solution prepared by the above-mentioned method was applied onto a glass substrate by inkjet printing. The glass substrate applied with the polyamic acid solution was first dried at 80° C. for 180 seconds in a chamber, and the pressure of the chamber was decreased from normal pressure to 10 torr during the first drying. Next, the glass substrate was second dried at 80° C. for 150 seconds in the same chamber, and the pressure of the chamber was decreased from 10 torr to 0.1 torr during the second drying. Accordingly, a preliminary organic layer was formed on the glass substrate.

### 3. Formation of Organic Layer

The glass substrate on which the preliminary organic layer was formed was placed in a heat treatment chamber, and the preliminary organic layer was heat treated. Heat treatment of the preliminary organic layer was carried out in four steps. The temperature of the preliminary organic layer was increased from 80° C. to 180° C. at a rate of 2.86° C./min for 35 minutes and the temperature of the preliminary organic layer was maintained at 180° C. for 15 minutes to first heat treat the preliminary organic layer. Next, the temperature of the preliminary organic layer was increased from 180° C. to 250° C. at a rate of 1.75° C./min for 40 minutes and the temperature of the preliminary organic layer was maintained at 250° C. for 15 minutes to second heat treat the preliminary organic layer. Next, the temperature of the preliminary organic layer was increased from 250° C. to 470° C. at a rate of 6.88° C./min for 32 minutes and the temperature of the preliminary organic layer was maintained at 470° C. for 23 minutes to third heat treat the preliminary organic layer. Next, the temperature of the preliminary organic layer was decreased from 470° C. to 100° C. for 50 minutes to form an organic layer.

### Comparative Example 1

In Comparative Example 1, an organic layer was prepared in the same manner as in Embodiment 1 described above, except that the dianhydride compound included only the BPDA and the diamine compound included only the PPD. In other words, the BPDA was included in an amount of 100 mol % based on the total mole number of the dianhydride compound, and the PPD was included in an amount of 100 mol % based on the total mole number of the diamine compound. That is, in Comparative Example 1, the dianhydride compound did not include an oxydiphthalic anhydride, and the diamine compound did not include an APAB and an ODA.

### Evaluation of Properties of Embodiment 1 and Comparative Example 1

The optical properties and heat resistance properties of the organic layer of Embodiment 1 and the organic layer of Comparative Example 1 formed by above-described method were evaluated. To evaluate optical properties, a transmittance at a wavelength of 450 nm was measured by a chromaticity and luminance measuring device (MCPD-3000, OSTKA, JAPAN).

To evaluate heat resistance properties, a CTE was measured by TMA (Q400) from TA Instrument Inc. The organic layer having a thickness of 10 μm formed by the above-described method was sampled in sizes of 2 mm×16 mm. The sampled organic layer was stabilized by fixation with a load of 0.03 N in a nitrogen environment, and then, the change in length of the sampled organic layer was measured. The CTE was evaluated by measuring the degree of expansion of the sampled organic layer in the longitudinal direction, that is, in a plan view. The CTE was measured at a temperature in a range of 100° C. to 300° C. That is, in Table 1, CTE represents the CTE based on the degree of expansion of the organic layer from 100° C. to 300° C.

A thermal decomposition temperature (Td) was measured by measuring mass loss according to temperature by TGA (Q600) from TA instrument Inc. The weight of the sample was set to be 4 mg (±0.2 mg). As with the measurement of the CTE, the measurement of a thermal decomposition temperature was also performed in a nitrogen environment. In Table 1, Td, 0.5 wt % represents a temperature at which mass is reduced by 0.5 wt % due to thermal decomposition, and Td, 1 wt % represents a temperature at which mass is reduced by 1 wt % due to thermal decomposition.

TABLE 1

| | |
|---|---|
| Embodiment 1 | Comparative Example 1 |

| | | |
|---|---|---|
| Transmittance | 80% | 65% |

| | | | | |
|---|---|---|---|---|
| CTE | 10.8 | ppm/° C. | 2.74 | ppm/° C. |
| Td, 0.5 wt % | 518.7° | C. | 574° | C. |
| Td, 1 wt % | 537.8° | C. | 591° | C. |

Referring to Table 1, the transmittance of the organic layer of Embodiment 1 was 80% and the transmittance of the organic layer of Comparative Example 1 was 65%. Therefore, the organic layer of Embodiment 1 had a higher transmittance compared to the organic layer of Comparative Example 1. The organic layer of Embodiment 1 had higher transparency compared to the organic layer of Comparative Example 1. That is, the organic layer of Embodiment 1 formed by an oxydiphthalic anhydride, a BPDA, an APAB, an ODA, and a PPD showed excellent optical properties compared to the organic layer of Comparative Example 1 formed by only a BPDA and a PPD.

In addition, the CTE of the organic layer of Embodiment 1 was 10.8 ppm/° C. and the thermal decomposition temperature of the organic layer of Embodiment 1 was greater than 500° C. Since the organic layer of Embodiment 1 had a CTE of less than 12 ppm/° C., the organic layer of Embodiment 1 may have dimensional stability even under relatively high temperature conditions. Since the organic layer of Embodiment 1 had a thermal decomposition temperature greater than 500° C., the organic layer of Embodiment 1 may have relatively high stability and reliability under relatively high temperature conditions. That is, the organic layer of Embodiment 1 formed by an oxydiphthalic anhydride, a BPDA, an APAB, an ODA, and a PPD showed excellent heat resistance properties comparable to that of the organic layer of Comparative Example 1 formed by only a BPDA and a PPD.

The organic layer of Embodiment 1 had the same or similar mechanical properties, adhesion, and reliability as the organic layer of Comparative Example 1. In an embodiment, the organic layer of Embodiment 1 had a modulus of 7 gigapascals (GPa) and an elongation rate of 21.9%, and the organic layer of Comparative Example 1 had a modulus of 9.8 GPa and an elongation rate of 26%. The organic layer of Embodiment 1 had an adhesion greater than 1,000 gram-force per inch (gf/in) and the organic layer of Comparative Example 1 had an adhesion greater than 1,000 gf/in. Under conditions of a temperature of 60° C. and 85% humidity, the organic layer of Embodiment 1 showed a moisture absorption result of 0.63%, and the organic layer of Comparative Example 1 showed a moisture absorption result of 1.18%. Under conditions of a temperature of 60° C. and 100% humidity, the organic layer of Embodiment 1 showed a moisture permeability result of 15 ram per square meter per day (g/m²·day), and the organic layer of Comparative Example 1 showed a moisture permeability result of 15 g/m²·day. That is, the organic layer of Embodiment 1 formed by an oxydiphthalic anhydride, a BPDA, an APAB, an ODA, and a PPD showed the same or similar mechanical properties, adhesion, and reliability as the organic layer of Comparative Example 1 formed by only a BPDA and a PPD.

Since the organic layer of the display apparatus in an embodiment has relatively high transmittance and relatively high transparency, a substrate for a display apparatus with improved optical properties may be implemented. Accordingly, it is possible to prevent or minimize light output from the component 40 under the organic layer to the outside or traveling toward the component 40 from the outside from being reduced or changed.

Additionally, since the organic layer of the display apparatus in an embodiment has a relatively high thermal decomposition temperature and a relatively low CTE, a substrate for a display apparatus having good heat resistance properties may be implemented. That is, the organic layer of the display apparatus in an embodiment may use an oxydiphthalic anhydride, a BPDA, an APAB, an ODA, and a PPD and undergo imidization thereof under the above-mentioned heat treatment conditions, thereby implementing a substrate for a display apparatus having excellent optical properties and good heat resistance properties.

While the disclosure has been described with reference to embodiments illustrated in the drawings, these embodiments are provided herein for illustrative purpose only, and one of ordinary skill in the art may understand that the embodiments include various modifications and equivalent embodiments thereof. Therefore, the true scope of technical protection of the disclosure should be determined by the technical spirit of the attached claims.

In an embodiment as described above, a display apparatus including a substrate having relatively high transparency and a method of manufacturing the same may be implemented. The scope of the disclosure is not limited by such effects.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. A display apparatus comprising:
a substrate in which a component area comprising sub-display areas and transmission areas and a main display area at least partially surrounding the component area are defined, the substrate comprising:
a first organic layer, a first barrier layer on the first organic layer;
a second organic layer on the first barrier layer; and
a second barrier layer on the second organic layer; and
display elements arranged on the main display area and the sub-display areas,
wherein each of the first organic layer and the second organic layer comprises a cured product of polyamic acid prepared by polymerizing an oxydiphthalic anhydride, a biphenyl-tetracarboxylic dianhydride, a 4-aminophenyl-4-aminobenzoate, a 4,4′-oxydianiline, and a p-phenylenediamine.

2. The display apparatus of claim 1, wherein a ratio of a sum of a mole number of the oxydiphthalic anhydride and a mole number of the biphenyl-tetracarboxylic dianhydride to a sum of a mole number of the 4-aminophenyl-4-aminobenzoate, a mole number of the 4,4′-oxydianiline, and a mole number of the p-phenylenediamine is 1:1.

3. The display apparatus of claim 1, wherein when a mole number of the oxydiphthalic anhydride is expressed as “a” and a mole number of the biphenyl-tetracarboxylic dianhydride is expressed as “b,” the mole number of the oxydiphthalic anhydride and the mole number of the biphenyl-tetracarboxylic dianhydride satisfy Equation 1 and Equation 2:
$$0.1 \leq \frac{a}{a + b} \leq 0.5 \qquad Equation 1$$
$$0.5 \leq \frac{b}{a + b} \leq 0.9 . \qquad Equation 2$$

4. The display apparatus of claim 1, wherein when a mole number of the 4-aminophenyl-4-aminobenzoate is expressed as “c,” a mole number of the 4,4′-oxydianiline is expressed as “d,” and a mole number of the p-phenylenediamine is expressed as “e,” the mole number of the 4-aminophenyl-4-aminobenzoate, the mole number of the 4,4′-oxydianiline, and the mole number of the p-phenylenediamine satisfy Equation 3, Equation 4, and Equation 5:
$$0.1 \leq \frac{c}{c + d + e} \leq 0.3 \qquad Equation 3$$
$$0.1 \leq \frac{d}{c + d + e} \leq 0.3 \qquad Equation 4$$
$$0.4 \leq \frac{e}{c + d + e} \leq 0.8 . \qquad Equation 5$$

5. The display apparatus of claim 1, wherein a transmittance of each of the first organic layer and the second organic layer at 450 nanometers is 80% or more.

6. The display apparatus of claim 1, wherein a coefficient of thermal expansion of each of the first organic layer and the second organic layer is less than 12 parts-per-million per degree Celsius.

7. The display apparatus of claim 1, wherein a thermal decomposition temperature of each of the first organic layer and the second organic layer is greater than 500 degrees Celsius.

8. The display apparatus of claim 1, wherein the first barrier layer is in direct contact with the second organic layer.

9. A method of manufacturing a display apparatus, the method comprising:
manufacturing a substrate in which a component area comprising sub-display areas and transmission areas and a main display area at least partially surrounding the component area are defined; and
forming a display element on the main display area and the sub-display areas,
wherein the manufacturing the substrate comprises:
preparing polyamic acid by polymerizing a dianhydride compound and a diamine compound;
forming a preliminary organic layer by applying the polyamic acid along with an organic solvent onto a manufacturing substrate and removing at least a portion of the organic solvent; and
forming an organic layer by curing the preliminary organic layer,
wherein the dianhydride compound comprises an oxydiphthalic anhydride and a biphenyl-tetracarboxylic dianhydride, and
the diamine compound comprises a 4-aminophenyl-4-aminobenzoate, a 4,4′-oxydianiline, and a p-phenylenediamine.

10. The method of manufacturing a display apparatus of claim 9, wherein a ratio of a sum of a mole number of the oxydiphthalic anhydride and a mole number of the biphenyl-tetracarboxylic dianhydride to a sum of a mole number of the 4-aminophenyl-4-aminobenzoate, a mole number of the 4,4′-oxydianiline, and a mole number of the p-phenylenediamine is 1:1.

11. The method of manufacturing a display apparatus of claim 9, wherein when a mole number of the oxydiphthalic anhydride is expressed as “a” and a mole number of the biphenyl-tetracarboxylic dianhydride is expressed as “b,” the mole number of the oxydiphthalic anhydride and the mole number of the biphenyl-tetracarboxylic dianhydride satisfy Equation 1 and Equation 2:
$$0.1 \leq \frac{a}{a + b} \leq 0.5 \qquad Equation 1$$
$$0.5 \leq \frac{b}{a + b} \leq 0.9 . \qquad Equation 2$$

12. The method of manufacturing a display apparatus of claim 9, wherein when a mole number of the 4-aminophenyl-4-aminobenzoate is expressed as “c,” a mole number of the 4,4′-oxydianiline is expressed as “d,” and a mole number of the p-phenylenediamine is expressed as “e,” the mole number of the 4-aminophenyl-4-aminobenzoate, the mole number of the 4,4′-oxydianiline, and the mole number of the p-phenylenediamine satisfy Equation 3, Equation 4, and Equation 5:
$$0.1 \leq \frac{c}{c + d + e} \leq 0.3 \qquad Equation 3$$
$$0.1 \leq \frac{d}{c + d + e} \leq 0.3 \qquad Equation 4$$
$$0.4 \leq \frac{e}{c + d + e} \leq 0.8 . \qquad Equation 5$$

13. The method of manufacturing a display apparatus of claim 9, wherein a transmittance of the organic layer at 450 nanometers is 80% or more.

14. The method of manufacturing a display apparatus of claim 9, wherein a coefficient of thermal expansion of the organic layer is less than 12 parts-per-million per degree Celsius.

15. The method of manufacturing a display apparatus of claim 9, wherein a thermal decomposition temperature of the organic layer is greater than 500 degrees Celsius.

16. The method of manufacturing a display apparatus of claim 9, wherein the forming the organic layer by curing the preliminary organic layer comprises:
first heat treating the preliminary organic layer and increasing a temperature of the preliminary organic layer from a first temperature to a second temperature higher than the first temperature;
second heat treating the preliminary organic layer and increasing the temperature of the preliminary organic layer from the second temperature to a third temperature higher than the second temperature;
third heat treating the preliminary organic layer and increasing the temperature of the preliminary organic layer from the third temperature to a fourth temperature higher than the third temperature; and
cooling the preliminary organic layer and decreasing the temperature of the preliminary organic layer from the fourth temperature to a fifth temperature lower than the fourth temperature,
wherein in the first heat treating the preliminary organic layer, a heating rate of the preliminary organic layer is in a range of about 2.50 degrees Celsius per minute to about 3.33 degrees Celsius per minute.

17. The method of manufacturing a display apparatus of claim 16, wherein, in the first heat treating the preliminary organic layer, the temperature of the preliminary organic layer is increased from the first temperature to the second temperature and the temperature of the preliminary organic layer is maintained at the second temperature.

18. The method of manufacturing a display apparatus of claim 16, wherein the first temperature is 80 degrees Celsius,
the second temperature is 180 degrees Celsius, and
in the first heat treating the preliminary organic layer, a time desired to increase the temperature of the preliminary organic layer from the first temperature to the second temperature is about 30 minutes to about 40 minutes.

19. The method of manufacturing a display apparatus of claim 16, wherein in the second heat treating the preliminary organic layer,
the temperature of the preliminary organic layer is increased from the second temperature to the third temperature and the temperature of the preliminary organic layer is maintained at the third temperature,
the second temperature is 180 degrees Celsius,
the third temperature is 250 degrees Celsius, and
in the second heat treating the preliminary organic layer, a heating rate of the preliminary organic layer is in a range of about 1.56 degrees Celsius per minute to about 2.00 degrees Celsius per minute.

20. The method of manufacturing a display apparatus of claim 16, wherein, in the third heat treating the preliminary organic layer, the temperature of the preliminary organic layer is increased from the third temperature to the fourth temperature and the temperature of the preliminary organic layer is maintained at the fourth temperature,
the third temperature is 250 degrees Celsius, and
the fourth temperature is 470 degrees Celsius, and
in the third heat treating the preliminary organic layer, a heating rate of the preliminary organic layer is in a range of about 5.95 degrees Celsius per minute to about 8.15 degrees Celsius per minute.
